(19) United States
(12) Patent Application Publication
(10) Pub. No.: US 2024/0215315 A1
(43) Pub. Date: Jun. 27, 2024

(54) THIN-FILM TRANSISTOR SUBSTRATE AND METHOD OF MANUFACTURING THIN-FILM TRANSISTOR

(71) Applicant: Xiamen Tianma Display Technology Co., Ltd., Xiamen (CN)

(72) Inventors: Jun TANAKA, Kawasaki (JP); Kazushige TAKECHI, Kawasaki (JP)

(21) Appl. No.: 18/530,651

(22) Filed: Dec. 6, 2023

(30) Foreign Application Priority Data
Dec. 26, 2022 (JP) 2022-207860
Aug. 8, 2023 (JP) 2023-129535

(51) Int. Cl. H10K 59/121; H10K 59/12

(52) U.S. Cl. CPC H10K 59/1213; H10K 59/1201

(57) ABSTRACT

A thin-film transistor includes a gate electrode and a layered oxide region between a substrate and the gate electrode. The layered oxide region includes a first oxide layer and a second oxide layer. A channel region includes a first region of the first oxide layer, and a source/drain region includes a second region of the first oxide layer and a first region of the second oxide layer laid one above the other. The mobility of the first oxide layer is greater than the mobility of the second oxide layer. The distance between a peak position in a concentration profile of a first impurity atoms in a layering direction and a top face of the first region of the second oxide layer is shorter than the distance between the peak position and a top face of the second region of the first oxide layer.

### CROSS-REFERENCE TO RELATED APPLICATIONS

This non-provisional application claims priority under 35 U.S.C. § 119(a) on Patent Application No. 2022-207860 filed in Japan on Dec. 26, 2022 and Patent Application No. 2023-129535 filed in Japan on Aug. 8, 2023, the entire contents of which are hereby incorporated by reference.

### BACKGROUND

This disclosure relates to a thin-film transistor substrate and a method of manufacturing a thin-film transistor.

Oxide thin-film transistors (TFTs) are used in various devices such as display devices including liquid crystal display devices and organic light-emitting diode (OLED) display devices and memory devices. Oxide thin-film transistors have a characteristic that generates low leakage current but have low mobility compared to low-temperature polysilicon TFTs. For this reason, oxide semiconductor material having high mobility has been studied.

The oxide layer of an oxide TFT includes a channel region and source/drain regions sandwiching the channel region. The source/drain regions are low-resistive regions that are less resistive than the channel region. The low-resistive region can be produced by exposing the oxide layer to plasma of a specific element or implanting impurity ions to the oxide layer.

### SUMMARY

An aspect of this disclosure is a thin-film transistor substrate including: a substrate; a thin-film transistor on the substrate, wherein the thin-film transistor includes: a gate electrode; a layered oxide region located between the substrate and the gate electrode; and a gate insulating layer located between the layered oxide region and the gate electrode, wherein the layered oxide region includes: a channel region covered with the gate electrode; source/drain regions located outer than the gate electrode; a first oxide layer made of a first oxide; and a second oxide layer made of a second oxide different from the first oxide, wherein the first oxide layer and the second oxide layer have an interface therebetween, wherein the channel region includes a first region of the first oxide layer, wherein each of the source/drain regions includes a second region of the first oxide layer and a first region of the second oxide layer laid one above the other, wherein the first region of the second oxide layer has a lower resistivity than the second region of the first oxide layer, wherein an amount of first impurity atoms required for the second region of the first oxide layer to have a resistivity equal to a resistivity of the first region of the second oxide layer is larger than an amount of the first impurity atoms contained in the first region of the second oxide layer, and wherein a distance between a peak position in a concentration profile of the first impurity atoms in a layering direction and a top face of the first region of the second oxide layer is shorter than a distance between the peak position and a top face of the second region of the first oxide layer.

Another aspect of this disclosure is a method of manufacturing a thin-film transistor, the method comprising: producing a layered oxide region including a first oxide layer and a second oxide layer laid one above the other; producing an insulating layer above the layered oxide region; producing a gate electrode above the insulating layer; and implanting impurity ions to the layered oxide region using the gate electrode as a mask to reduce resistivity of parts of the second oxide layer, wherein an amount of impurity ions to be implanted for the first oxide layer to have a resistivity equal to a resistivity of the parts of the second oxide layer is larger than an amount of impurity ions implanted to the parts of the second oxide layer, and wherein a distance between a peak position of a concentration profile of impurity ions in the implanting and a top face of the second oxide layer is shorter than a distance between the peak position and a top face of the first oxide layer.

It is to be understood that both the foregoing general description and the following detailed description are exemplary and explanatory and are not restrictive of this disclosure.

### BRIEF DESCRIPTION OF THE DRAWINGS

FIG. 1 schematically illustrates a configuration example of an OLED display device.

FIG. 2 illustrates a configuration example of a pixel circuit.

FIG. 3 schematically illustrates a cross-sectional structure of a part of a TFT substrate.

FIG. 4 is a cross-sectional diagram schematically illustrating a structure of a multilayer oxide TFT.

FIG. 5 illustrates an example of impurity ion implantation to the multilayer oxide TFT.

FIG. 6A illustrates a step of manufacturing a multilayer oxide TFT.

FIG. 6B illustrates a step of manufacturing a multilayer oxide TFT.

FIG. 6C illustrates a step of manufacturing a multilayer oxide TFT.

FIG. 6D illustrates a step of manufacturing a multilayer oxide TFT.

FIG. 7 is a cross-sectional diagram schematically illustrating another structural example of a multilayer oxide TFT.

FIG. 8 illustrates an example of impurity ion implantation to the multilayer oxide TFT.

FIG. 9 is a cross-sectional diagram schematically illustrating still another structural example of a multilayer oxide TFT.

FIG. 10 illustrates an example of impurity ion implantation to the multilayer oxide TFT.

FIG. 11 is a cross-sectional diagram schematically illustrating still another structural example of a multilayer oxide TFT.

FIG. 12 is a cross-sectional diagram schematically illustrating still another structural example of a multilayer oxide TFT.

FIG. 13 is a cross-sectional diagram schematically illustrating still another structural example of a multilayer oxide TFT.

FIG. 14 is a cross-sectional diagram schematically illustrating still another structural example of a multilayer oxide TFT.

FIG. 15 illustrates an example of impurity ion implantation to the multilayer oxide TFT.

FIG. 16 is a cross-sectional diagram schematically illustrating still another structural example of a multilayer oxide TFT.

FIG. 17 illustrates an example of impurity ion implantation to the multilayer

oxide TFT.

FIG. 18 is a schematic plan diagram of a structural example of the multilayer oxide TFT in FIG. 14.

FIG. 19A illustrates the cross-section of the example of FIG. 18 along the center line of the channel width.

FIG. 19B illustrates the cross-section of the example of FIG. 18 along an end of the channel width.

FIG. 20A provides a result of evaluation on the reliability of a TFT.

FIG. 20B provides a result of evaluation on the reliability of another TFT.

FIG. 20C provides a result of evaluation on the reliability of still another TFT.

### EMBODIMENTS

Hereinafter, embodiments of this disclosure will be described with reference to the accompanying drawings. It should be noted that the embodiments are merely examples to implement this disclosure and are not to limit the technical scope of this disclosure. Some elements in the drawings are exaggerated in size or shape for clear understanding of the description.

### Overview

The following description employs an organic light-emitting diode (OLED) display device as an example of a device including a thin-film transistor substrate. The OLED display device in this disclosure includes an oxide thin-film transistor (TFT) in a pixel circuit and/or a peripheral circuit. The oxide TFT in this disclosure is applicable to not only an OLED display device but also flat panel display devices such as a liquid crystal display device and electronic devices such as a memory device and a high-voltage device.

A TFT includes source/drain regions and a channel region located between the source/drain regions. The source/drain regions have a lower resistivity than the channel region. The term source/drain is a generic term of source or drain. For example, terms such as source/drain region, source/drain electrode, and source/drain terminal are referred to. A source/drain can become a source or a drain depending on the direction of the flow of carriers in the channel region.

Oxide TFTs have a characteristic that generates low leakage current. For this reason, oxide TFTs can be employed for a pixel circuit and a peripheral circuit such as a scanning circuit of an OLED display device.

One of the known techniques to improve the characteristics of an oxide TFT is layering different oxide materials. In the meanwhile, reducing the resistivity by implanting impurity ions makes a smaller difference AL between the designed channel length and the effective channel length and consequently, enables the TFT to have a shorter channel than reducing the resistivity with plasma. However, the inventors' research revealed that some oxide materials need to be doped with more impurity ions than the other oxide materials to have low resistivity.

An embodiment of this specification discloses a top-gate oxide TFT having a layered oxide region. The layered oxide region includes a first oxide layer and a second oxide layer. The channel region of the oxide TFT includes a first region of the first oxide layer and each source/drain region includes a second region of the first oxide layer and a first region of the second oxide layer laid one above the other. The amount of impurities to be implanted to sufficiently reduce the resistivity of the oxide of the first oxide layer is larger than the amount of impurities to be implanted to sufficiently reduce the resistivity of the oxide of the second oxide layer. The distance between the peak position in the concentration profile of the impurity atoms in the layering direction and the top face of the second oxide layer is smaller than the distance between the peak position and the top face of the first oxide layer. This configuration enables efficient manufacture of the thin-film transistor including a multilayer oxide film.

### Embodiment 1

### Configuration of Display Device

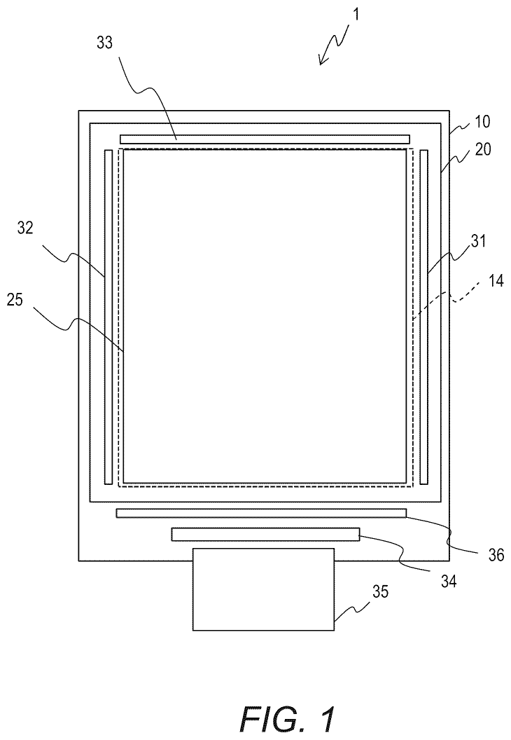

FIG. 1 schematically illustrates a configuration example of an OLED display device 1. The OLED display device 1 includes a thin-film transistor (TFT) substrate on which OLED elements and pixel circuits are fabricated, a thin-film encapsulation (TFE) 20 for encapsulating the OLED elements. The thin-film encapsulation 20 is a kind of a structural encapsulation unit. Another example of a structural encapsulation unit can include an encapsulation substrate for encapsulating organic light-emitting elements and a bond (glass frit sealer) for bonding the TFT substrate 10 with the encapsulation substrate. The space between the TFT substrate 10 and the encapsulation substrate is filled with dry nitrogen, for example.

In the periphery of a cathode electrode region 14 outer than the display region 25 of the TFT substrate 10, a scanning driver 31, an emission driver 32, a protection circuit 33, a driver IC 34, and a demultiplexer 36 are provided. The driver IC 34 is connected to the external devices via flexible printed circuits (FPC) 35. The scanning driver 31, the emission driver 32, and the protection circuit 33 are peripheral circuits fabricated on the TFT substrate 10.

The scanning driver 31 drives scanning lines on the TFT substrate 10. The emission driver 32 drives emission control lines to control the light emission periods of pixels. The driver IC 34 is mounted with an anisotropic conductive film (ACF), for example.

The protection circuit 33 protects the elements in the pixel circuits from electrostatic discharge. The driver IC 34 provides power and a timing signal (control signal) to the scanning driver 31 and the emission driver 32 and further, provides power and a data signal to the demultiplexer 36.

The demultiplexer 36 outputs output of one pin of the driver IC 34 to d data lines serially (d is an integer larger than 1). The demultiplexer 36 changes the data line to output the data signal from the driver IC 34 d times per scanning period to drive d times as many data lines as output pins of the driver IC 34.

### Configuration of Pixel Circuit

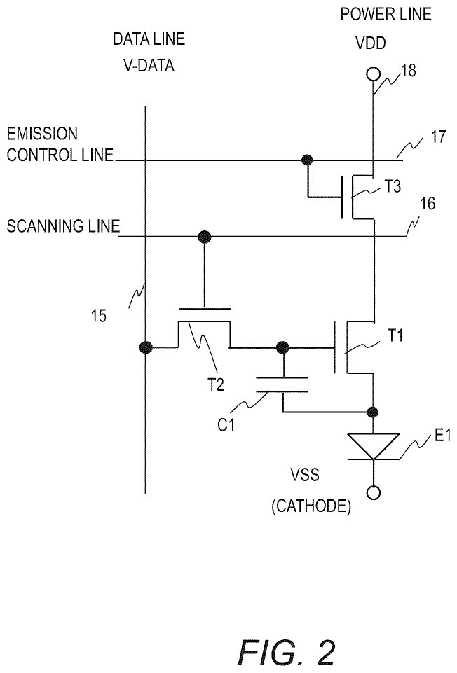

A plurality of pixel circuits are fabricated on the TFT substrate 10 to control electric current to be supplied to the anode electrodes of subpixels (also simply referred to as pixels). FIG. 2 illustrates a simple configuration example of a pixel circuit. Each pixel circuit includes a driving transistor T1, a selection transistor T2, an emission transistor T3, and a storage capacitor C1. The pixel circuit controls light emission of an OLED element E1. The transistors are TFTs. The transistors except for the driving transistor T1 are switching transistors.

The selection transistor T2 is a switch for selecting the pixel. The selection transistor T2 is an n-channel type of oxide TFT and its gate terminal is connected to a scanning line 16. One of the source/drain terminals is connected to a data line 15. The other source/drain terminal is connected to the gate terminal of the driving transistor T1.

The driving transistor T1 is a transistor (driving TFT) for driving the OLED element E1. The driving transistor T1 is an n-channel type of oxide TFT and its gate terminal is connected to a source/drain terminal of the selection transistor T2. The drain terminal of the driving transistor T1 is connected to the source terminal of the emission transistor T3 and the source terminal of the driving transistor T1 is connected to the OLED element E1. The storage capacitor C1 is provided between the gate terminal and the source terminal of the driving transistor T1.

The emission transistor T3 is a switch for controlling supply/stop of the driving current to the OLED element E1. The emission transistor T3 is an n-channel type of oxide TFT and its gate terminal is connected to an emission control line 17. The drain terminal of the emission transistor T3 is connected to a power line 18 and the source terminal of the emission transistor T3 is connected to the drain terminal of the driving transistor T1.

Operation of the pixel circuit is described. The scanning driver 31 outputs a selection pulse to the scanning line 16 to turn on the selection transistor T2. The data voltage supplied from the driver IC 34 through the data line 15 is stored to the storage capacitor C1. The storage capacitor C1 holds the stored voltage throughout the period of one frame. The conductance of the driving transistor T1 changes in an analog manner in accordance with the stored voltage, so that the driving transistor T1 supplies a forward bias current corresponding to an emission level to the OLED element E1.

The emission transistor T3 is located on the supply path of the driving current. The emission driver 32 outputs a control signal to the emission control line 17 to control ON/OFF of the emission transistor T3. When the emission transistor T3 is ON, the driving current is supplied to the OLED element E1. When the emission transistor T3 is OFF, this supply is stopped. The lighting period (duty ratio) in the period of one frame can be controlled by controlling ON/OFF of the transistor T3. The circuit configuration in FIG. 2 is merely an example; the pixel circuit can have a different configuration.

### Configuration of TFT Substrate

A configuration example of a TFT substrate including oxide TFTs having a multilayer structure is described. An oxide TFT having a multilayer structure includes a plurality of oxide layers deposited one above another. A plurality of oxide regions deposited one above another is referred to as a layered oxide region and a TFT including a layered oxide region is also referred to as a multilayer oxide TFT. The layered oxide region includes oxide layers composed of different materials. The different materials are different in combination of constituent elements or different in composition distribution under the same combination of constituent elements. That is to say, the same or different materials mean materials having the same or different elemental compositions and the elemental composition means the kinds of the constituent elements and their distribution. The elemental composition refers to the major elements and does not include the impurities to reduce the resistivity. The details of the layered oxide region will be described later.

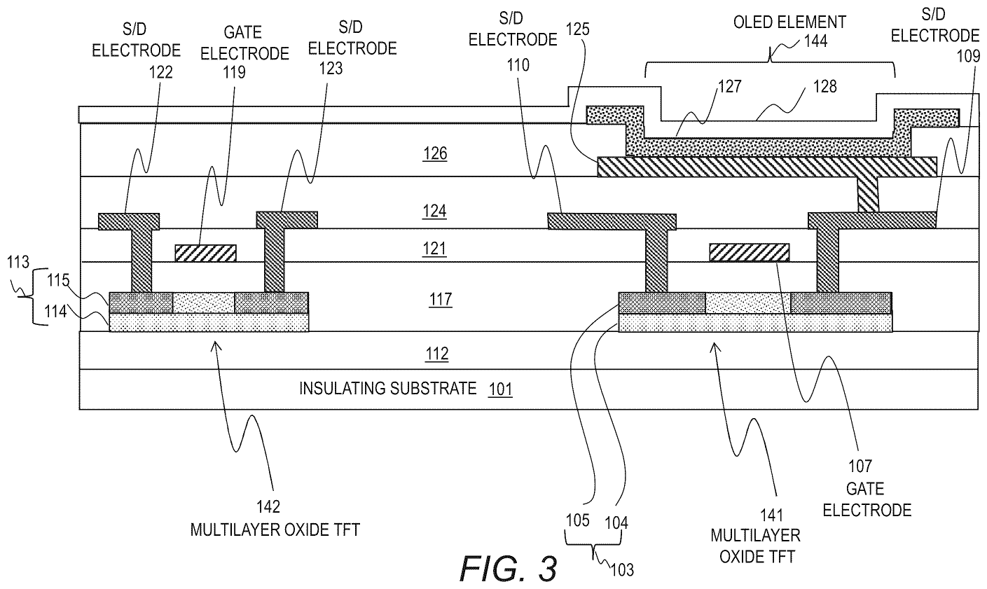

FIG. 3 schematically illustrates a cross-sectional structure of a part of a TFT substrate. A multilayer oxide TFT 141, another multilayer oxide TFT 142, and an OLED element 144 are fabricated on an insulating substrate 101. These elements correspond to the driving transistor T1, the selection transistor T2, and the OLED element E1 in FIG. 2.

The insulating substrate 101 is a flexible or inflexible substrate made of resin or glass, and can have a single-layer or multilayer structure. An insulator layer 112 covers the top face of the insulating substrate 101. In this description, a position closer to the insulating substrate 101 is a lower position and a position farther from the insulating substrate 101 is an upper position. With respect to each layer or film, the side closest to the insulating substrate 101 is an undersurface and the opposite side is a top face.

The oxide TFT 141 includes an oxide region 103 having a multilayer structure. The layered oxide region 103 is provided above the insulator layer 112. In the configuration example of FIG. 3, the layered oxide region 103 includes a lower oxide region 104 and an upper oxide region 105. The lower oxide region 104 and the upper oxide region 105 are included in different oxide layers. Each oxide layer includes oxide regions of a plurality of oxide TFTs.

The layered oxide region 103 includes source/drain regions and a channel region located between the source/drain regions in an in-plane direction. Each source/drain region includes oxide layers reduced in resistivity and the channel region is made of oxides not reduced in resistivity and it is covered with a gate electrode. The channel region has a higher resistivity than the source/drain regions.

The oxide TFT 141 has a top-gate structure. The oxide TFT 141 can have a bottom gate in addition to the top gate. The oxide TFT 141 includes a gate electrode 107 and a gate insulator region located between the gate electrode 107 and the channel region in the layering direction. The gate insulator region is a part of an insulator layer 117 located between the gate electrode 107 and the channel region. The insulator layer 117 is made of a silicon oxide, for example.

The channel region, the gate insulator region, and the gate electrode 107 are stacked in this order from the bottom (the side closer to the substrate); the gate insulator region is in contact with the channel region and the gate electrode 107. The gate electrode 107 is made of a conductor and included in a conductor layer. The gate electrode 107 can be made of a metal. The metal material can be selected desirably; for example, Mo, W, Nb, or Al can be employed.

An insulator layer 121 is deposited to cover the oxide region 103, the gate insulator region, and the gate electrode 107 of the oxide TFT 141 and the insulator layer 117. The insulator layer 121 can be made of a silicon oxide, for example.

Source/drain electrodes 109 and 110 are provided above the insulator layer 121 and they are in direct contact with the source/drain regions via contact holes opened through the insulator layers 121 and 117. The source/drain electrodes 109 and 110 can be made of Al or Ti, for example.

The oxide TFT 142 includes an oxide region 113 having a multilayer structure. The layered oxide region 113 is provided above the insulator layer 112. In the configuration example of FIG. 3, the layered oxide region 113 includes a lower oxide region 114 and an upper oxide region 115. The lower oxide region 114 and the upper oxide region 115 are included in different oxide layers. The lower oxide region 114 is included in the same layer as the lower oxide region 104 (produced by the same process) and the upper oxide region 115 is included in the same layer as the upper oxide region 105.

The layered oxide region 113 includes source/drain regions and a channel region located between the source/drain regions in an in-plane direction. Each source/drain region includes oxide layers reduced in resistivity and the channel region is made of oxides not reduced in resistivity and it is covered with a gate electrode. The channel region has a higher resistivity than the source/drain regions. The details of the layered oxide region 113 will be described later.

The oxide TFT 142 has a top-gate structure. The oxide TFT 142 can have a bottom gate in addition to the top gate. The oxide TFT 142 includes a gate electrode 119 and a gate insulator region located between the gate electrode 119 and the channel region in the layering direction. The gate insulator region is a part of the insulator layer 117 located between the gate electrode 119 and the channel region.

The channel region, the gate insulator region, and the gate electrode 119 are stacked in this order from the bottom (the side closer to the substrate); the gate insulator region is in contact with the channel region and the gate electrode 119. The gate electrode 119 is made of a conductor and included in the same conductor layer as the gate electrode 107. The insulator layer 121 is deposited to cover the oxide region 113, the gate insulator region, and the gate electrode 119 of the oxide TFT 142.

Source/drain electrodes 122 and 123 of the oxide TFT 142 are provided above the insulator layer 121 and they are in direct contact with the source/drain regions of the oxide TFT 142 via contact holes opened through the insulator layers 121 and 117. The source/drain electrodes 122 and 123 are included in the same metal layer (conductor layer) as the source/drain electrodes 109 and 110.

A planarization film 124 having insulating properties is laid to cover the exposed parts of the aforementioned conductor layer and the insulator layer 121. The planarization film 124 can be made of an organic material. An anode electrode 125 is provided above the planarization film 124. The anode electrode 125 is connected to the source/drain electrode 109 of the oxide TFT 141 via a contact hole opened through the planarization film 124.

The anode electrode 125 can include three layers of a transparent film of ITO or IZO, a reflective film of a metal such as Ag, Mg, Al, or Pt or an alloy containing such a metal, and another transparent film as mentioned above, for example. This three-layer structure of the anode electrode 125 is merely an example; the anode electrode 125 can have a bilayer structure.

Above the anode electrode 125, a pixel defining layer 126 having insulating properties is provided to isolate the OLED element 144. The pixel defining layer 126 can be made of an organic material. An organic light-emitting film 127 is provided above the anode electrode 125. The organic light-emitting film 127 consists of, for example, a hole injection layer, a hole transport layer, a light-emitting layer, an electron transport layer, and an electron injection layer in this order from the bottom. The multilayer structure of the organic light-emitting film 127 is determined depending on the design.

Furthermore, a cathode electrode 128 is provided above the organic light-emitting film 127. The cathode electrode 128 of one OLED element 144 is a part of an unseparated conductor film. The cathode electrode 128 transmits part of the visible light coming from the organic light-emitting film 127. The stack of the anode electrode 125, the organic light-emitting film 127, and the cathode electrode 128 provided within an opening of the pixel defining layer 126 corresponds to an OLED element 144.

### Configuration Example of Multilayer Oxide TFT

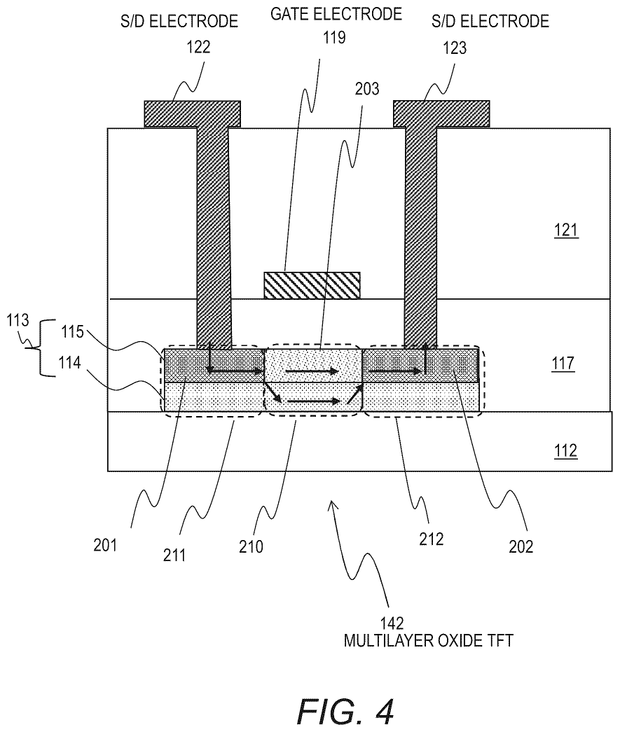

The configuration of a multilayer oxide TFT is described in detail. FIG. 4 is a cross-sectional diagram schematically illustrating the structure of the multilayer oxide TFT 142. The layered oxide region 113 consists of a lower oxide region 114 and an upper oxide region 115; there is an interface between the oxide regions 114 and 115. The lower oxide region 114 and the upper oxide region 115 are made of oxides composed of different materials.

The upper oxide region 115 includes a highly-resistive region 203 covered with the gate electrode 119 and low-resistive regions 201 and 202 sandwiching the highly-resistive region 203 in an interlayer direction. The source/drain electrodes 122 and 123 are in contact with the top faces of the low-resistive regions 201 and 202. The low-resistive regions 201 and 202 have a resistivity lower than 10⁻⁴ Ω·cm, for example. As will be described later, the low-resistive region can be produced by implanting impurity ions to the oxide.

The lower oxide region 114 substantially does not need to be reduced in resistivity. The lower oxide region 114 does not have a low-resistive region having a resistivity low enough to be a source/drain region by itself. The lower oxide region 114 has higher resistivity than the low-resistive regions 201 and 202 in any part.

The layered oxide region 113 includes a channel region 210 and source/drain regions 211 and 212 sandwiching the channel region 210 in an interlayer direction. The channel region 210 has a higher resistivity than the source/drain regions 211 and 212. The channel region 210 in the layered oxide region 113 has a multilayer structure. Specifically, the channel region 210 covered with the gate electrode 119 consists of a part of the lower oxide region 114 and the highly-resistive region 203 of the upper oxide region 115.

The source/drain regions 211 and 212 in the layered oxide region 113 have a multilayer structure. Specifically, the source/drain region 211 consists of a part of the lower oxide region 114 and a part of the low-resistive region 201 of the upper oxide region 115. The source/drain region 212 consists of another part of the lower oxide region 114 and a part of the low-resistive region 202 of the upper oxide region 115.

The arrows in the layered oxide region 113 in FIG. 4 schematically represent electric current when the gate electrode 119 is supplied with a high-level potential and the multilayer oxide TFT 142 is ON. In this example, assume that the source/drain electrode 122 is a drain electrode and the source/drain electrode 123 is a source electrode. The current flows through the low-resistive region 201 in the source/drain region 211, the two layers of the channel region 210, and the low-resistive region 202 in the source/drain region 212. Each of the source/drain regions 211 and 212 consists of a highly-resistive lower layer and a low-resistive upper layer and its overall resistivity is lower than the resistivity of the channel region 210.

The multilayer structure of the channel region 210 improves the ON-current characteristics of the channel region 210. In an embodiment of this specification, the lower oxide region 114 (an example of a first oxide layer) has a higher mobility than the upper oxide region 115 (an example of a second oxide layer). This configuration improves the ON-current characteristics of the channel region 210 more. High mobility across two oxides means a small band gap.

### Impurity Concentration Profile of Layered Oxide Region

The concentration profile of the impurities in a multilayer oxide TFT is described. An embodiment of this specification produces low-resistive regions in the layered oxide region of the multilayer oxide TFT by implanting impurity ions. Examples of the impurity element to be selected to cause resistivity reduction include B, He, Ne, Ar, H, and P. Compared to reducing the resistivity with hydrogen plasma, impurity ion implantation attains a small AL of the channel, enabling a multilayer oxide TFT to have a short channel.

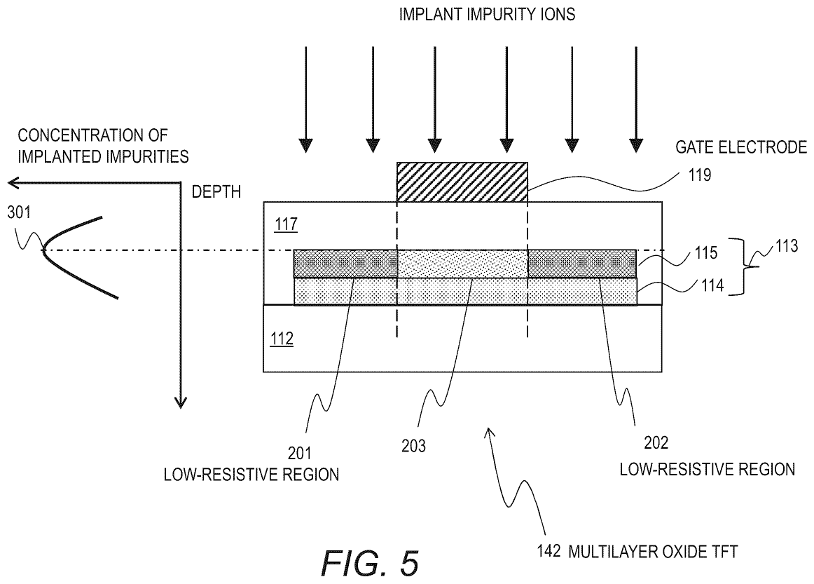

FIG. 5 illustrates an example of impurity ion implantation to the multilayer oxide TFT 142. The impurity ions can be B ions. Impurity ions are implanted to the multilayer oxide TFT 142 in the state illustrated in FIG. 5, using the gate electrode 119 as a mask, so that low-resistive regions 201 and 202 are produced in the upper oxide region 115. The region 203 sandwiched by the low-resistive regions 201 and 202 in an interlayer direction is a part of the highly-resistive channel region.

FIG. 5 includes a schematic concentration profile of the implanted impurity atoms in the layering direction. The impurity concentration profile can be adjusted by controlling the voltage for accelerating the impurity ions and the amount of impurity ions to be implanted. The peak position of the impurity concentration (the target position in implantation) can be adjusted by controlling the voltage for accelerating the impurity ions. The concentration of the impurities can be adjusted by controlling the amount of impurity ions to be implanted.

The impurity concentration profile in the example of FIG. 5 has one peak 301, which is located closer to the top face of the upper oxide region 115 than the top face of the lower oxide region 114. In other words, the distance between the location of the peak 301 and the top face of the upper oxide region 115 is shorter than the distance between the location of the peak 301 and the top face of the lower oxide region 114. In the example of FIG. 5, the peak 301 is located in the vicinity of the top face (including the top face itself) of the upper oxide region 115. This configuration enables efficient production of the low-resistive regions 201 and 202 in the upper oxide region 115. Although the peak 301 in FIG. 5 is located on the top face of the upper oxide region 115, the peak 301 can be located slightly above or below the top face of the upper oxide region 115.

For the configuration example of a multilayer oxide TFT 142 illustrated in FIGS. 4 and 5, producing low-resistive regions having the same resistivity as the low-resistive regions 201 and 202 of the upper oxide region 115 in the lower oxide region 114 requires more impurity ions (impurity atoms) than those implanted to the low-resistive regions 201 and 202 in the upper oxide region 115. Accordingly, although impurity ions are implanted to the source/drain regions in the lower oxide region 114, their amount is not enough to reduce the resistivity of the regions to the level to make single-layer source/drain regions.

Implanting impurity ions for resistivity reduction suitably for the upper oxide region 115 leads to efficient production of source/drain regions with a smaller amount of impurity ions. As described with reference to FIG. 4, most of the electric current that flows within the source/drain regions 211 and 212 flows through the low-resistive regions 201 and 202 of the upper oxide region 115. The low-resistive regions 201 and 202 can provide characteristics required for the source/drain regions 211 and 212.

In an embodiment of this specification, the lower oxide region 114 has higher mobility than the oxide of the upper oxide region 115. For example, the oxide of the lower oxide region 114 is IGZO (In:Ga:Zn=2:2:1) and the oxide of the upper oxide region 115 is IGZO (In:Ga:Zn=1:1:1). This configuration improves the characteristics of the TFT.

The inventors' research revealed that many oxide materials having high mobility need implantation of a large amount of impurity ions to attain low resistivity. Accordingly, employing an oxide having high mobility for the lower oxide region 114, employing an oxide having low mobility for the upper oxide region 115, and implanting impurity ions targeting the upper oxide region 115 achieve improvement in characteristics and efficient manufacture of the oxide TFT.

In many of the high-mobility oxide materials, carrier conduction in the In-O system is utilized. An example of such material is IGZO. Increasing the composition ratio of indium in the oxide increases the carrier concentration and the mobility. However, the inventors' research revealed that many oxides having a high composition ratio of indium need implantation of a large amount of impurity ions (impurity atoms) to attain low resistivity.

In an embodiment of this specification, the atomic percentage of indium in the combination of elements other than oxygen of the lower oxide region 114 is higher than the atomic percentage of indium in the combination of elements other than oxygen of the upper oxide region 115.

The atomic percentage of indium in the combination of elements other than oxygen of the lower-layer oxide is not less than 50 atm % and the atomic percentage of indium in the combination of elements other than oxygen of the upper-layer oxide is less than 50 atm %. For example, the lower oxide region 114 is made of IGZO (In:Ga:Zn=6:2:1) and the upper oxide region 115 is made of IGZO (In:Ga:Zn=1:1:1). As noted from this example, the lower oxide region 114 and the upper oxide region 115 can be made of the same combination of elements, In, Ga, Zn, and O, but can contain different atomic percentages of In.

### Manufacture of Multilayer Oxide TFT

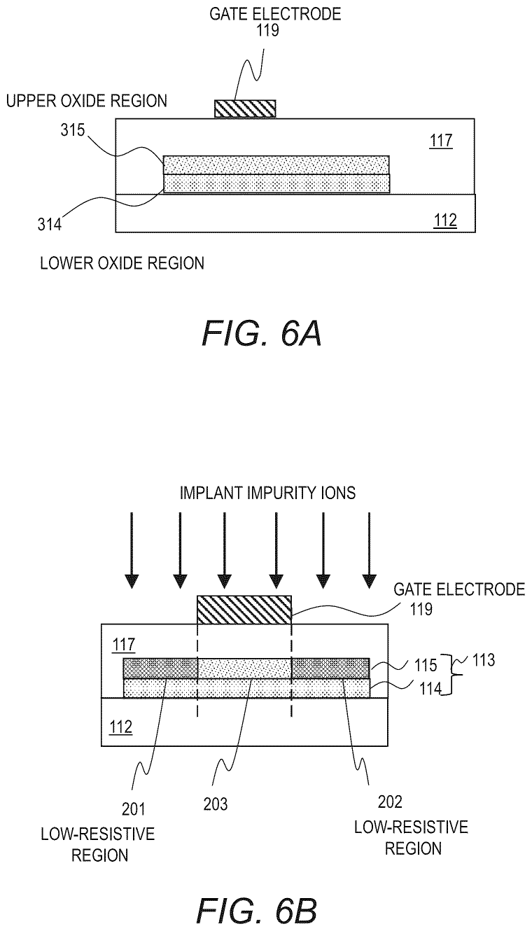

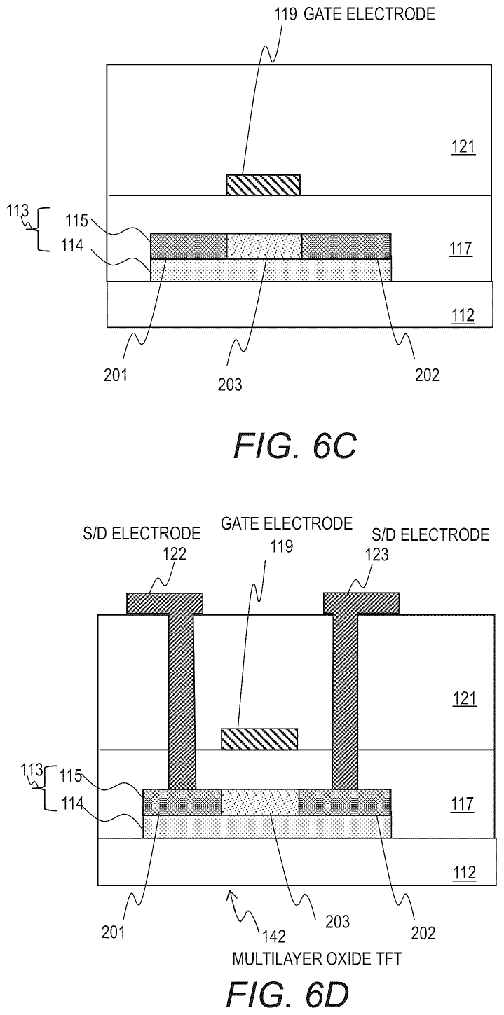

An example of the method of manufacturing a multilayer oxide TFT is described. With reference to FIG. 6A, the manufacturing method produces an insulator layer 112 by chemical vapor deposition (CVD) and thereafter, produces a layered oxide region consisting of a lower oxide region 314 and an upper oxide region 315. Producing the layered oxide region includes depositing multiple oxide layers by sputtering and patterning the oxide layers by photolithography.

Next, the method produces an insulator layer 117 by CVD. The method further deposits a metal film by sputtering and etches the metal film with a mask patterned by photolithography to form a gate electrode 119.

With reference to FIG. 6B, the method implants impurity ions (for example, boron ions) to the layered oxide region across the insulator layer 117. The lower oxide region 314 and the upper oxide region 315 turn into a lower oxide region 114 and an upper oxide region 115, respectively. Low-resistive regions 201 and 202 are produced in the upper oxide region by the impurity ion implantation. The region between these low-resistive regions is a highly-resistive region 203.

Although the lower oxide region 114 contains impurity atoms in the regions outer than the gate electrode 119, the resistivity of the regions is higher than the resistivity of the low-resistive regions 201 and 202. The resistivity of these regions can be lower than the resistivity of the region of the lower oxide region 114 covered with the gate electrode 119 (the region corresponding to a part of the channel region). The concentration profile of the impurity ions is as described with reference to FIG. 5.

With reference to FIG. 6C, the method produces an insulator layer 121 to cover the gate electrode 119 and the insulator layer 117. The insulator layer 121 can be produced by CVD. With reference to FIG. 6D, the method opens contact holes in the insulator layers 121 and 117 by etching with a mask patterned by photolithography. The method further deposits a metal film by sputtering, patterns a mask by photolithography, and etching the metal film to form source/drain electrodes 122 and 123.

### Embodiment 2

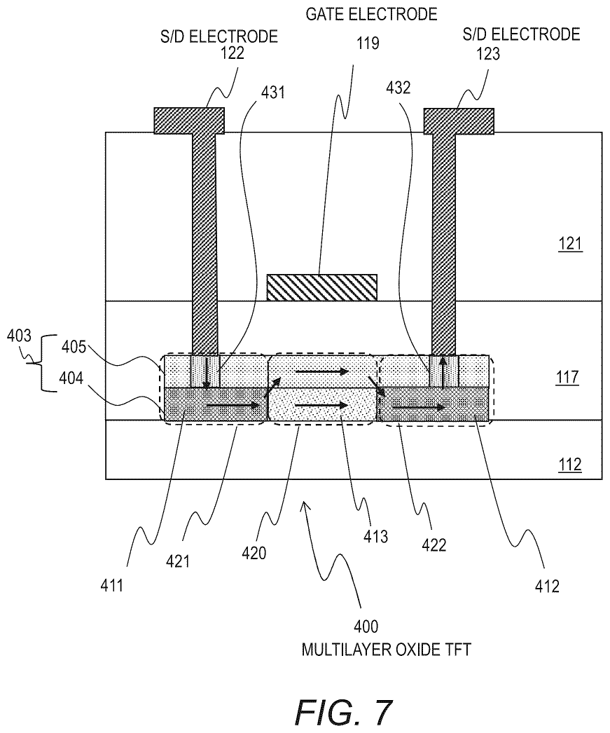

Another configuration example of a multilayer oxide TFT is described. FIG. 7 is a cross-sectional diagram schematically illustrating another structural example of a multilayer oxide TFT. In the following, differences from the structural example of FIG. 4 are mainly described. The multilayer oxide TFT 400 includes a layered oxide region 403. The layered oxide region 403 consists of a lower oxide region 404 and an upper oxide region 405 and there is an interface therebetween.

The lower oxide region 404 and the upper oxide region 405 are made of oxides composed of different materials. For example, the lower oxide region 404 can be made of the same material as the upper oxide region 115 described with reference to FIGS. 4 and 5 and the upper oxide region 405 can be made of the same material as the lower oxide region 114.

The oxide (lower-layer oxide) of the lower oxide region 404 (an example of the second oxide layer) can be an oxide having relatively low mobility and the oxide (upper-layer oxide) of the upper oxide region 405 (an example of the first oxide layer) can be an oxide having relatively high mobility. The atomic percentage (atm %) of indium in the combination of elements other than oxygen of the upper-layer oxide is higher than the atomic percentage of indium in the combination of elements other than oxygen of the lower-layer oxide. For example, the atomic percentage of indium in the combination of elements other than oxygen of the upper-layer oxide is not less than 50 atm % and the atomic percentage of indium in the combination of elements other than oxygen of the lower-layer oxide is less than 50 atm %.

The lower oxide region 404 includes a highly-resistive region 413 covered with a gate electrode 119 and low-resistive regions 411 and 412 sandwiching the highly-resistive region 413 in an interlayer direction. The low-resistive regions 411 and 412 are produced by implanting impurity ions.

The upper oxide region 405 consists of low-resistive regions 431 and 432 and a highly-resistive region other than the low-resistive regions 431 and 432. The top faces of the low-resistive regions 431 and 432 are in contact with source/drain electrodes 122 and 123 and the undersurfaces of the low-resistive regions 431 and 432 are in contact with the low-resistive regions 411 and 412 of the lower oxide region 404. The low-resistive regions 431 and 432 are produced because the upper oxide region 405 is in contact with the metallic source/drain electrodes 122 and 123. The low-resistive regions 431 and 432 have lower resistivity than the highly-resistive region 413.

The layered oxide region 403 includes a channel region 420 and source/drain regions 421 and 422 sandwiching the channel region 420 in an interlayer direction. The channel region 420 has a higher resistivity than the source/drain regions 421 and 422. The channel region 420 has a multilayer structure. Specifically, the channel region 420 consists of the highly-resistive region 413 of the lower oxide region 404 and a part of the highly-resistive region of the upper oxide region 405.

The source/drain regions 421 and 422 have a multilayer structure. Specifically, the source/drain region 421 consists of a part of the low-resistive region 411 of the lower oxide region 404, a low-resistive region 431 of the upper oxide region 405, and a part of the highly-resistive region of the upper oxide region 405. The source/drain region 422 consists of a part of the low-resistive region 412 of the lower oxide region 404, a low-resistive region 432 of the upper oxide region 405, and a part of the highly-resistive region of the upper oxide region 405.

In the configuration example of FIG. 7, electric current mainly flows through the low-resistive region 431, the low-resistive region 411, the two layers of the channel region 420, the low-resistive region 412, and the low-resistive region 432 when the gate electrode 119 is supplied with a high-level potential and the multilayer oxide TFT 400 is ON. The source/drain regions 421 and 422 have lower resistivity than the channel region 420.

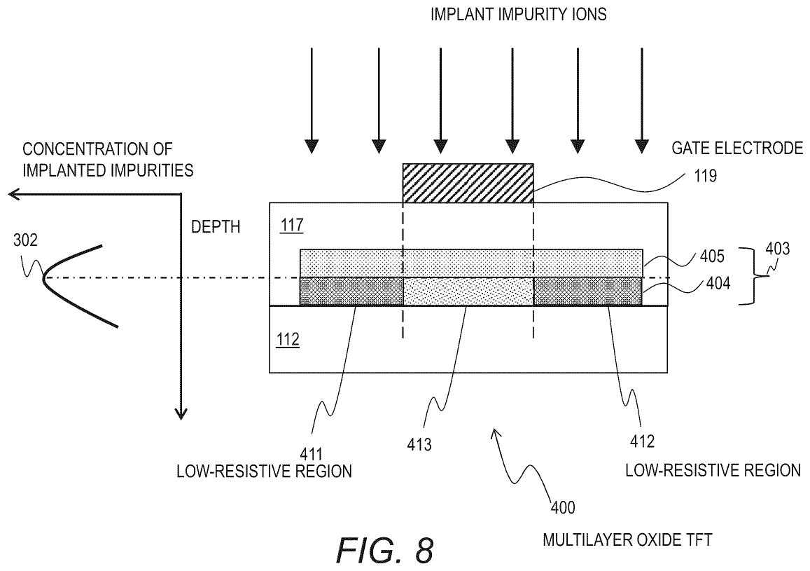

FIG. 8 illustrates an example of impurity ion implantation to the multilayer oxide TFT 400. The impurity ions can be B ions. Impurity ions are implanted to the multilayer oxide TFT in the state illustrated in FIG. 8, using the gate electrode 119 as a mask, so that the low-resistive regions 411 and 412 are produced in the lower oxide region 404. The region 413 sandwiched by the low-resistive regions 411 and 412 in an interlayer direction is a part of the highly-resistive channel region.

FIG. 8 includes a schematic concentration profile of the implanted impurity atoms in the layering direction. The impurity concentration profile in the example of FIG. 8 has one peak 302, which is located closer to the top face of the lower oxide region 404 than the top face of the upper oxide region 405. In other words, the distance between the location of the peak 302 and the top face of the lower oxide region 404 is shorter than the distance between the location of the peak 302 and the top face of the upper oxide region 405. In the example of FIG. 8, the peak 302 is located in the vicinity of the top face (including the top face itself) of the lower oxide region 404. This configuration enables efficient production of the low-resistive regions 411 and 412 in the lower oxide region 404. Although the peak 302 in FIG. 8 is located on the top face of the lower oxide region 404, the peak 302 can be located slightly above or below the top face of the lower oxide region 404.

The multilayer oxide TFT 400 described with reference to FIGS. 7 and 8 can be manufactured as described with reference to FIGS. 6A to 6D. Implanting impurity ions can be controlled as described with reference to FIG. 8.

### Embodiment 3

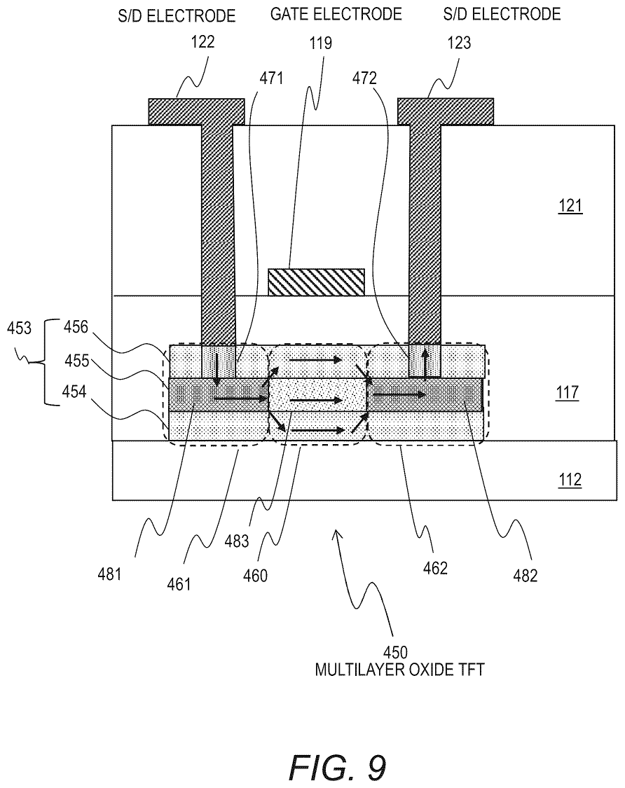

Still another configuration example of a multilayer oxide TFT is described. FIG. 9 is a cross-sectional diagram schematically illustrating still another structural example of a multilayer oxide TFT. In the following, differences from the structural example of FIG. 4 are mainly described. The multilayer oxide TFT 450 includes a layered oxide region 453. The layered oxide region 453 consists of a lower oxide region 454, an intermediate oxide region 455, and an upper oxide region 456. There are interfaces between the lower oxide region 454 and the intermediate oxide region 455 and between the upper oxide region 456 and the intermediate oxide region 455.

The lower oxide region 454 can be made of the same material and can have the same structure as the lower oxide region 114 in FIG. 4. The intermediate oxide region 455 can be made of the same material and can have the same structure as the upper oxide region 115 in FIG. 4. The upper oxide region 456 and the intermediate oxide region 455 are made of oxides composed of different materials. The upper oxide region 456 and the lower oxide region 454 (an example of the first oxide layer) can be made of an oxide composed of the same material or oxides composed of different materials.

For example, the oxide (upper-layer oxide) of the upper oxide region 456 (an example of a third oxide layer) is an oxide having relatively high mobility and the oxide (intermediate-layer oxide) of the intermediate oxide region 455 (an example of the second oxide layer) is an oxide having relatively low mobility. The atomic percentage (atm %) of indium in the combination of elements other than oxygen of the upper-layer oxide is higher than the atomic percentage of indium in the combination of elements other than oxygen of the intermediate-layer oxide. For example, the atomic percentage of indium in the combination of elements other than oxygen of the upper-layer oxide is not less than 50 atm % and the atomic percentage of indium in the combination of elements other than oxygen of the intermediate-layer oxide is less than 50 atm %.

The upper oxide region 456 consists of low-resistive regions 471 and 472 and a highly-resistive region other than the low-resistive regions 471 and 472. The top faces of the low-resistive regions 471 and 472 are in contact with source/drain electrodes 122 and 123 and the undersurfaces of the low-resistive regions 471 and 472 are in contact with low-resistive regions 481 and 482 of the intermediate oxide region 455. The low-resistive regions 471 and 472 are produced because the upper oxide region 456 is in contact with the metallic source/drain electrodes 122 and 123. The low-resistive regions 471 and 472 have lower resistivity than a highly-resistive region 483 of the intermediate oxide region 455.

The layered oxide region 453 includes a channel region 460 and source/drain regions 461 and 462 sandwiching the channel region 460 in an interlayer direction. The channel region 460 has a higher resistivity than the source/drain regions 461 and 462. The channel region 460 has a multilayer structure. Specifically, the channel region 460 consists of a part of the highly-resistive region of the lower oxide region 454, the highly-resistive region 483 of the intermediate oxide region 455, and a part of the highly-resistive region of the upper oxide region 456.

The source/drain regions 461 and 462 have a multilayer structure. Specifically, the source/drain region 461 consists of a part of the highly-resistive region of the lower oxide region 454, a part of the low-resistive region 481 of the intermediate oxide region 455, the low-resistive region 471 of the upper oxide region 456, and a part of the highly-resistive region of the upper oxide region 456. The source/drain region 462 consists of a part of the highly-resistive region of the lower oxide region 454, a part of the low-resistive region 482 of the intermediate oxide region 455, the low-resistive region 472 of the upper oxide region 456, and a part of the highly-resistive region of the upper oxide region 456.

In the configuration example of FIG. 9, electric current mainly flows through the low-resistive region 471, the low-resistive region 481, the three layers of the channel region 460, the low-resistive region 482, and the low-resistive region 472 when the gate electrode 119 is supplied with a high-level potential and the multilayer oxide TFT 450 is ON. The source/drain regions 461 and 462 have lower resistivity than the channel region 460.

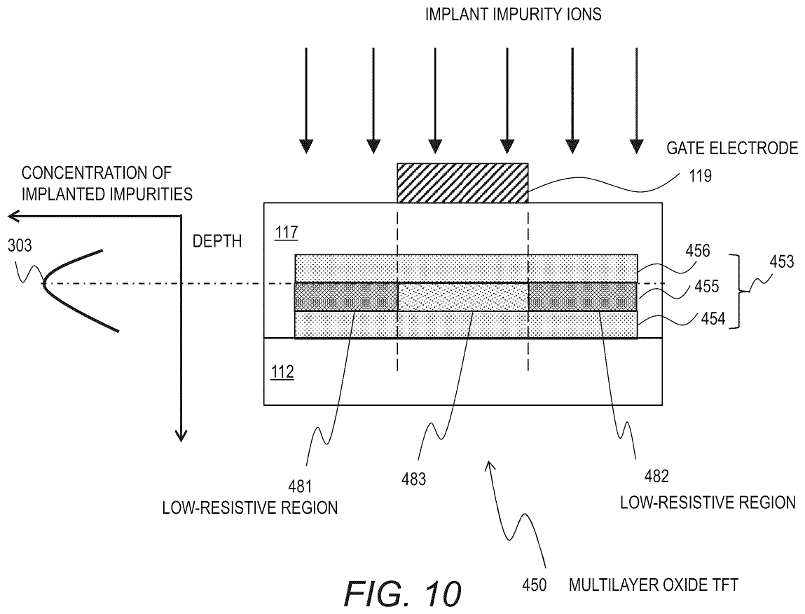

FIG. 10 illustrates an example of impurity ion implantation to the multilayer oxide TFT 450. The impurity ions can be B ions. Impurity ions are implanted to the multilayer oxide TFT in the state of FIG. 10, using the gate electrode 119 as a mask, so that the low-resistive regions 481 and 482 are produced in the intermediate oxide region 455. The region 483 sandwiched by the low-resistive regions 481 and 482 in an interlayer direction is a part of the highly-resistive channel region.

FIG. 10 includes a schematic concentration profile of the implanted impurity ions in the layering direction. The impurity concentration profile in the example of FIG. 10 has one peak 303, which is located closer to the top face of the intermediate oxide region 455 than the top face of the upper oxide region 456 or the top face of the lower oxide region 454. In other words, the distance between the location of the peak 303 and the top face of the intermediate oxide region 455 is shorter than the distance between the location of the peak 303 and the top face of the upper oxide region 456 or the distance between the location of the peak 303 and the top face of the lower oxide region 454.

In the example of FIG. 10, the peak 303 is located in the vicinity of the top face (including the top face itself) of the intermediate oxide region 455. This configuration enables efficient production of the low-resistive regions 481 and 482 in the intermediate oxide region 455. Although the peak 303 in FIG. 10 is located on the top face of the intermediate oxide region 455, the peak 303 can be located slightly above or below the top face of the intermediate oxide region 455.

The multilayer oxide TFT 450 described with reference to FIGS. 9 and 10 can be manufactured as described with reference to FIGS. 6A to 6D. Implanting impurity ions can be controlled as described with reference to FIG. 10. The layered oxide region can consist of oxide regions of four or more layers.

### Embodiment 4

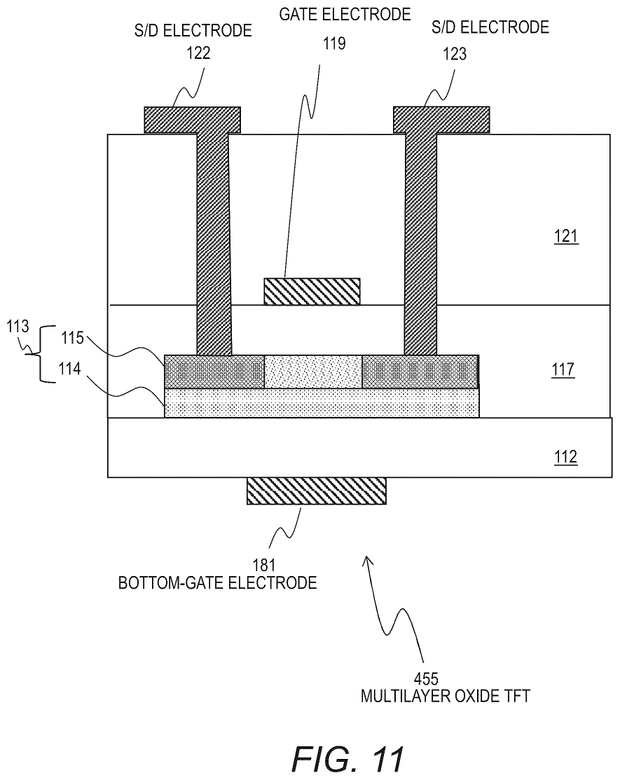

Still other configuration examples of a multilayer oxide TFT are described. FIGS. 11 to 13 are cross-sectional diagrams schematically illustrating still other structural examples of a multilayer oxide TFT. The multilayer oxide TFT 455 in FIG. 11 includes a bottom-gate electrode 181 in addition to the configuration of the multilayer oxide TFT 142 in FIG. 4. At least a part of the bottom-gate electrode 181 is opposed to the channel region of the layered oxide region 113 in the layering direction. A part of the insulator layer 112 located between the bottom-gate electrode 181 and the layered oxide region 113 corresponds to a bottom-gate insulating film. The bottom-gate electrode 181 can be supplied with a potential equal to or different from the potential for the gate electrode 119 (top-gate electrode).

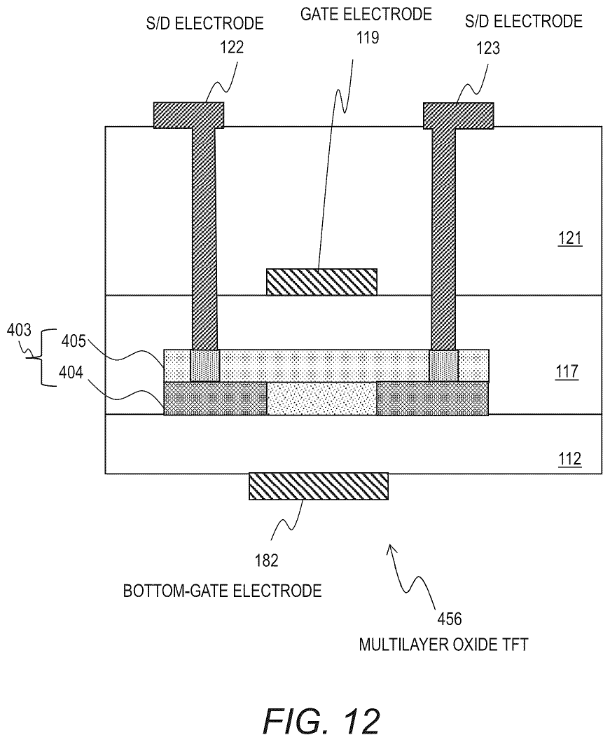

The multilayer oxide TFT 456 in FIG. 12 includes a bottom-gate electrode 182 in addition to the configuration of the multilayer oxide TFT 400 in FIG. 7. At least a part of the bottom-gate electrode 182 is opposed to the channel region of the layered oxide region 403 in the layering direction. A part of the insulator layer 112 located between the bottom-gate electrode 182 and the layered oxide region 403 corresponds to a bottom-gate insulating film. The bottom-gate electrode 182 can be supplied with a potential equal to or different from the potential for the gate electrode 119 (top-gate electrode).

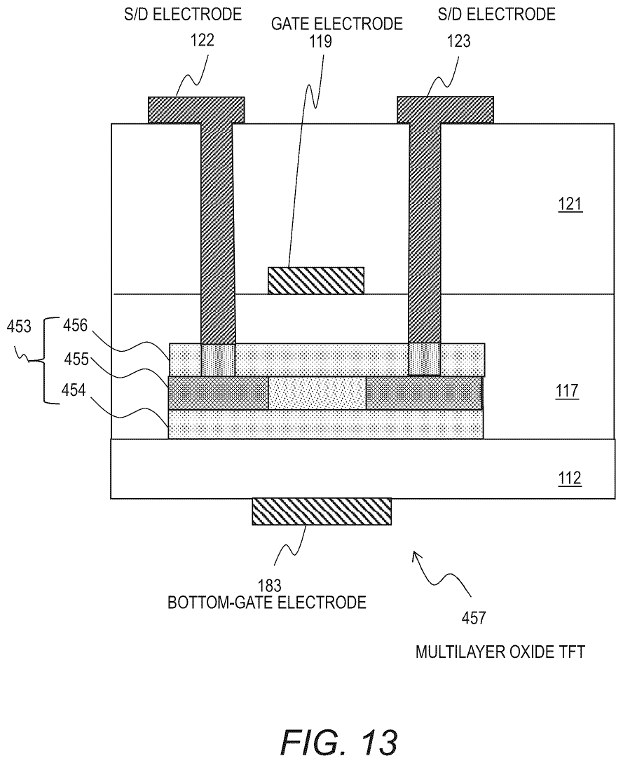

The multilayer oxide TFT 457 in FIG. 13 includes a bottom-gate electrode 183 in addition to the configuration of the multilayer oxide TFT 450 in FIG. 9. At least a part of the bottom-gate electrode 183 is opposed to the channel region of the layered oxide region 453 in the layering direction. A part of the insulator layer 112 located between the bottom-gate electrode 183 and the layered oxide region 453 corresponds to a bottom-gate insulating film. The bottom-gate electrode 183 can be supplied with a potential equal to or different from the potential for the gate electrode 119 (top-gate electrode).

### Embodiment 5

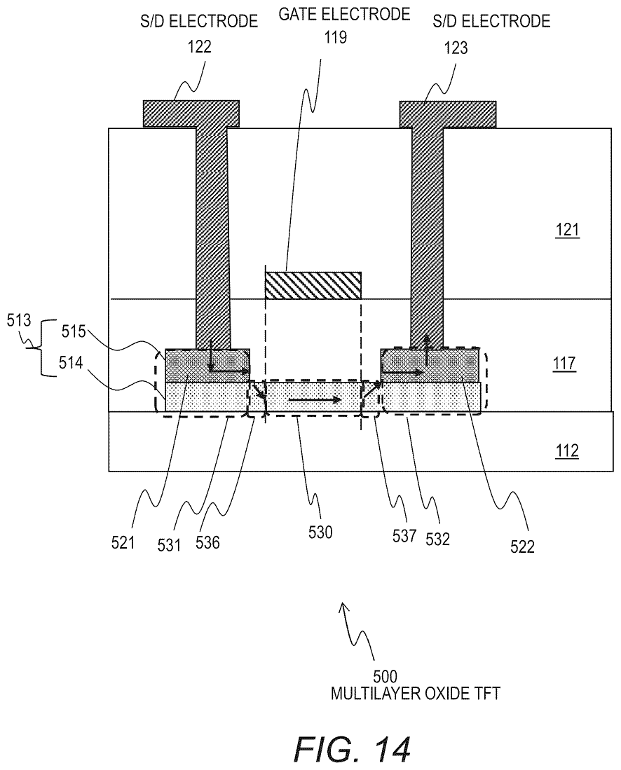

Still another configuration example of a multilayer oxide TFT is described. FIG. 14 is a cross-sectional diagram schematically illustrating still another structural example of a multilayer oxide TFT. In the following, differences from the structural example of FIG. 4 are mainly described. The multilayer oxide TFT to be described in the following includes offset regions that are more resistive than the source/drain regions between the channel region and each source/drain region. This configuration improves the drain breakdown voltage of the multilayer oxide TFT.

The multilayer oxide TFT 500 includes a layered oxide region 513. The layered oxide region 513 consists of a lower oxide region 514 and an upper oxide region 515. There is an interface between the lower oxide region 514 and the upper oxide region 515. The lower oxide region 514 (an example of the first oxide layer) can be made of the same oxide as the lower oxide region 114 in FIG. 4. The upper oxide region 515 (an example of the second oxide layer) can be made of the same oxide as the upper oxide region 115 in FIG. 4.

The upper oxide region 515 is patterned on the lower oxide region 514; a region including the region overlapping the gate electrode 119 is removed. The upper oxide region 515 includes low-resistive regions 521 and 522. The region between the low-resistive regions 521 and 522 is removed; a part of the top face of the lower oxide region 514 and the insulator layer 117 have an interface.

The lower oxide region 514 substantially does not need to be reduced in resistivity. The lower oxide region 514 does not have a low-resistive region having a resistivity low enough to be a source/drain region by itself. The lower oxide region 514 has higher resistivity than the low-resistive regions 521 and 522 in any part. The layered oxide region 513 includes a channel region 530 and source/drain

regions 531 and 532 sandwiching the channel region 530 in an interlayer direction. The layered oxide region 513 further includes an offset region 536 between the channel region 530 and the source/drain region 531 and another offset region 537 between the channel region 530 and the source/drain region 532. The offset regions 536 and 537 are located outer than the gate electrode 119 when viewed in the layering direction (in a planar view).

The channel region 530 has a single-layer structure. Specifically, the channel region 530 covered with the gate electrode 119 is a part of the lower oxide region 514. Making the lower oxide region 514 of a high-mobility oxide improves the channel characteristics of the TFT. The source/drain regions 531 and 532 have a multilayer structure. Specifically, the source/drain region 531 consists of a part of the lower oxide region 514 and a part of the low-resistive region 521 of the upper oxide region 515. The source/drain region 532 consists of another part of the lower oxide region 514 and a part of the low-resistive region 522 of the upper oxide region 515. The offset regions 536 and 537 are parts of the lower oxide region 514.

Electric current mainly flows through the low-resistive region 521 of the source/drain region 531, the offset region 536, the channel region 530, the offset region 537, and the low-resistive region 522 of the source/drain region 532 when the gate electrode 119 is supplied with a high-level potential and the multilayer oxide TFT 500 is ON. The electric current is restricted by the offset regions 536 and 537. The multilayer oxide TFT 500 can additionally have a bottom-gate electrode.

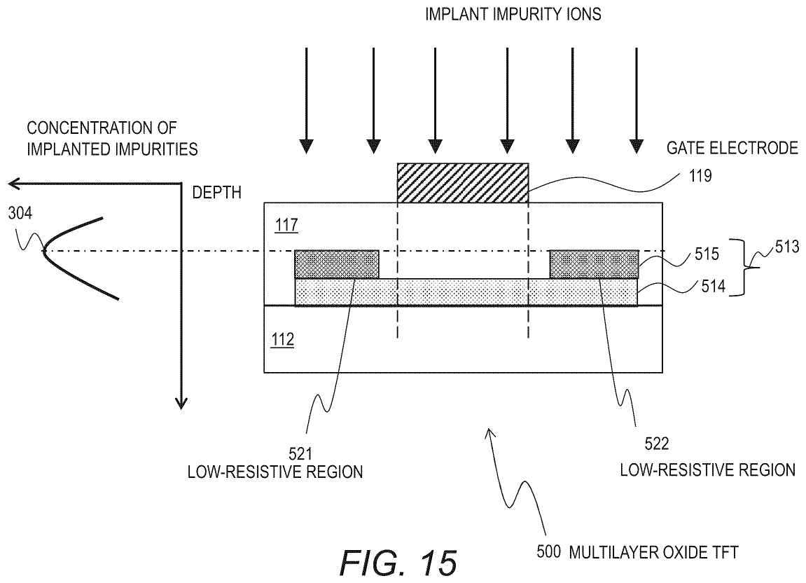

FIG. 15 illustrates an example of impurity ion implantation to the multilayer oxide TFT 500. The impurity ions can be B ions. Impurity ions are implanted to the upper oxide region 515 in the state illustrated in FIG. 15 where the region covered with the gate electrode 119 has been removed by patterning using the gate electrode 119 as a mask, so that the low-resistive regions 521 and 522 are produced.

FIG. 15 includes a schematic concentration profile of the implanted impurity atoms in the layering direction. The impurity concentration profile in the example of FIG. 15 has one peak 304, which is located closer to the top face of the upper oxide region 515 than the top face of the lower oxide region 514. In other words, the distance between the location of the peak 304 and the top face of the upper oxide region 515 is shorter than the distance between the location of the peak 304 and the top face of the lower oxide region 514.

In the example of FIG. 15, the peak 304 is located in the vicinity of the top face (including the top face itself) of the upper oxide region 515. This configuration enables efficient production of the low-resistive regions 521 and 522 in the upper oxide region 515. Although the peak 304 in FIG. 15 is located on the top face of the upper oxide region 515, the peak 304 can be located slightly above or below the top face of the upper oxide region 515.

The multilayer oxide TFT 500 described with reference to FIGS. 14 and 15 can be manufactured by adding a step of pattering the upper oxide region 515 to the method described with reference to FIGS. 6A to 6D. Implanting impurity ions can be controlled as described with reference to FIG. 15.

### Embodiment 6

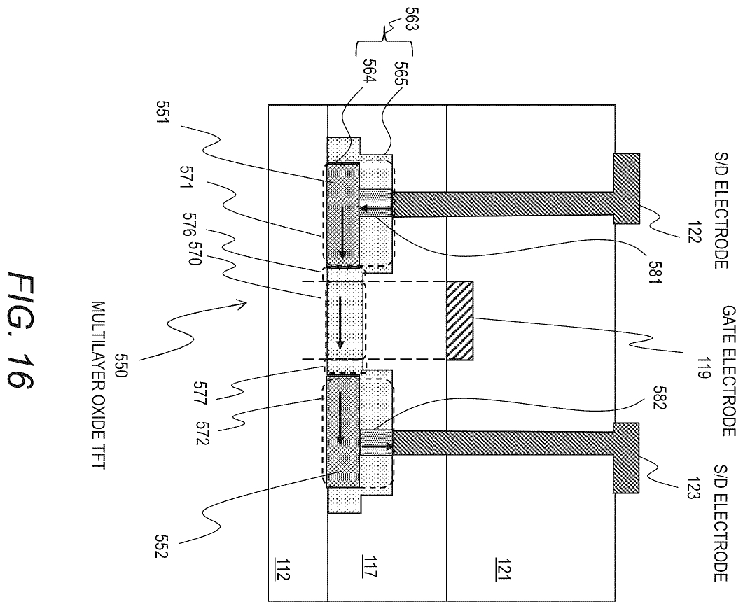

Still another configuration example of a multilayer oxide TFT is described. FIG. 16 is a cross-sectional diagram schematically illustrating still another structural example of a multilayer oxide TFT. In the following, differences from the structural example of FIG. 4 are mainly described. The multilayer oxide TFT to be described in the following includes offset regions that are more resistive than the source/drain regions between the channel region and each source/drain region. This configuration improves the drain breakdown voltage of the multilayer oxide TFT.

The multilayer oxide TFT 550 includes a layered oxide region 563. The layered oxide region 563 consists of a lower oxide region 564 and an upper oxide region 565. There is an interface between the lower oxide region 564 and the upper oxide region 565. The lower oxide region 564 is patterned on the insulator layer 112; a region including the region overlapping the gate electrode 119 is removed. The lower oxide region 564 includes low-resistive regions 551 and 552. The low-resistive regions 551 and 552 are produced by impurity ion implantation. The region between the low-resistive regions 551 and 552 are removed and a part of the undersurface of the upper oxide region 565 and the insulator layer 112 have an interface.

The lower oxide region 564 and the upper oxide region 565 are made of oxides composed of different materials. For example, the lower oxide region 564 (an example of the second oxide layer) can be made of the same oxide as the upper oxide region 115 described with reference to FIGS. 4 and 5 and the upper oxide region 565 (an example of the first oxide layer) can be made of the same oxide as the lower oxide region 114.

The oxide (lower-layer oxide) of the lower oxide region 564 can be an oxide having relatively low mobility and the oxide (upper-layer oxide) of the upper oxide region 565 can be an oxide having relatively high mobility. The atomic percentage (atm %) of indium in the combination of elements other than oxygen of the upper-layer oxide is higher than the atomic percentage of indium in the combination of elements other than oxygen of the lower-layer oxide. For example, the atomic percentage of indium in the combination of elements other than oxygen of the upper-layer oxide is not less than 50 atm % and the atomic percentage of indium in the combination of elements other than oxygen of the lower-layer oxide is less than 50 atm %.

The upper oxide region 565 consists of low-resistive regions 581 and 582 and a highly-resistive region other than the low-resistive regions 581 and 582. The top faces of the low-resistive regions 581 and 582 are in contact with source/drain electrodes 122 and 123 and the undersurfaces of the low-resistive regions 581 and 582 are in contact with the low-resistive regions 551 and 552 of the lower oxide region 564. The low-resistive regions 581 and 582 are produced because the upper oxide region 565 is in contact with the metallic source/drain electrodes 122 and 123. The low-resistive regions 581 and 582 have lower resistivity than the channel region 570.

The layered oxide region 563 includes the channel region 570 and source/drain regions 571 and 572 sandwiching the channel region 570 in an interlayer direction. The layered oxide region 563 further includes an offset region 576 between the source/drain region 571 and the channel region 570 and another offset region 577 between the channel region 570 and the source/drain region 572. The source/drain regions 571 and 572 and the offset regions 576 and 577 are located outer than the gate electrode 119 when viewed in the layering direction (in a planar view).

The channel region 570 and the offset regions 576 and 577 have higher resistivities than the source/drain regions 571 and 572. The channel region 570 has a single-layer structure. Specifically, the channel region 570 is a part of the highly-resistive region of the upper oxide region 565. Making the upper oxide region 565 of a high-mobility oxide improves the channel characteristics.

The source/drain regions 571 and 572 have a multilayer structure. Specifically, the source/drain region 571 consists of a part of the low-resistive region 551 of the lower oxide region 564, the low-resistive region 581 of the upper oxide region 565, and a part of the highly-resistive region of the upper oxide region 565. The source/drain region 572 consists of a part of the low-resistive region 552 of the lower oxide region 564, the low-resistive region 582 of the upper oxide region 565, and a part of the highly-resistive region of the upper oxide region 565. The offset regions 576 and 577 are parts of the highly-resistive region of the upper oxide region 565.

In the configuration example of FIG. 16, electric current mainly flows through the low-resistive region 581, the low-resistive region 551, the offset region 576, the channel region 570, the offset region 577, the low-resistive region 552, and the low-resistive region 582. The electric current is restricted by the offset region 576 and 577. The multilayer oxide TFT 550 can additionally have a bottom-gate electrode.

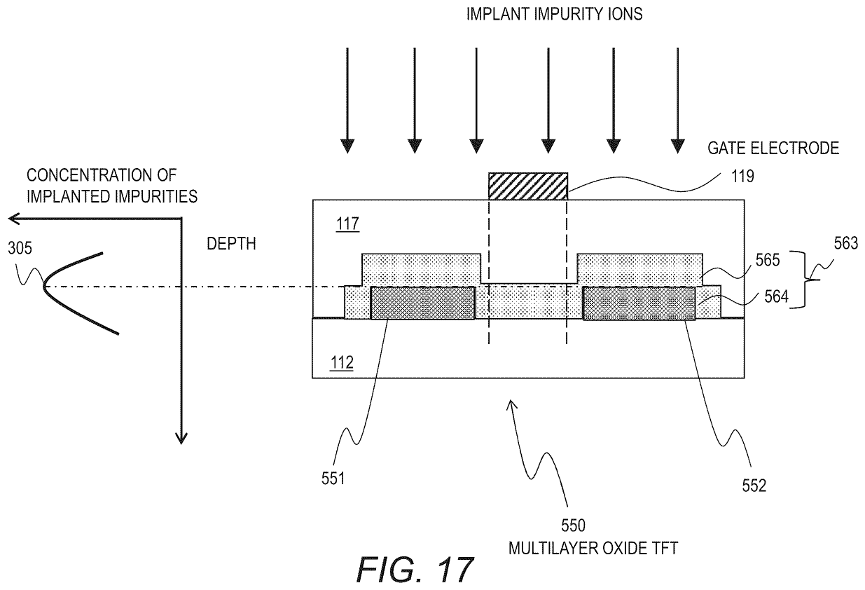

FIG. 17 illustrates an example of impurity ion implantation to the multilayer oxide TFT 550. The impurity ions can be B ions. Impurity ions are implanted to the lower oxide region 564 in the state illustrated in FIG. 17 where the region covered with the gate electrode 119 is removed by patterning using the gate electrode 119 as a mask, so that the low-resistive regions 551 and 552 are produced.

FIG. 17 includes a schematic concentration profile of the implanted impurity atoms in the layering direction. The impurity concentration profile in the example of FIG. 17 has one peak 305, which is located closer to the top face of the lower oxide region 564 than the top face of the upper oxide region 565. In other words, the distance between the location of the peak 305 and the top face of the lower oxide region 564 is shorter than the distance between the location of the peak 305 and the top face of the upper oxide region 565. In the example of FIG. 17, the peak 305 is located in the vicinity of the top face (including the top face itself) of the lower oxide region 564. This configuration enables efficient production of the low-resistive regions 551 and 552 in the lower oxide region 564. Although the peak 305 in FIG. 17 is located on the top face of the lower oxide region 564, the peak 305 can be located slightly above or below the top face of the lower oxide region 564.

The multilayer oxide TFT 550 described with reference to FIGS. 16 and 17 can be manufactured by adding a step of pattering the lower oxide region 564 to the method described with reference to FIGS. 6A to 6D. Implanting impurity ions can be controlled as described with reference to FIG. 17.

### Embodiment 7

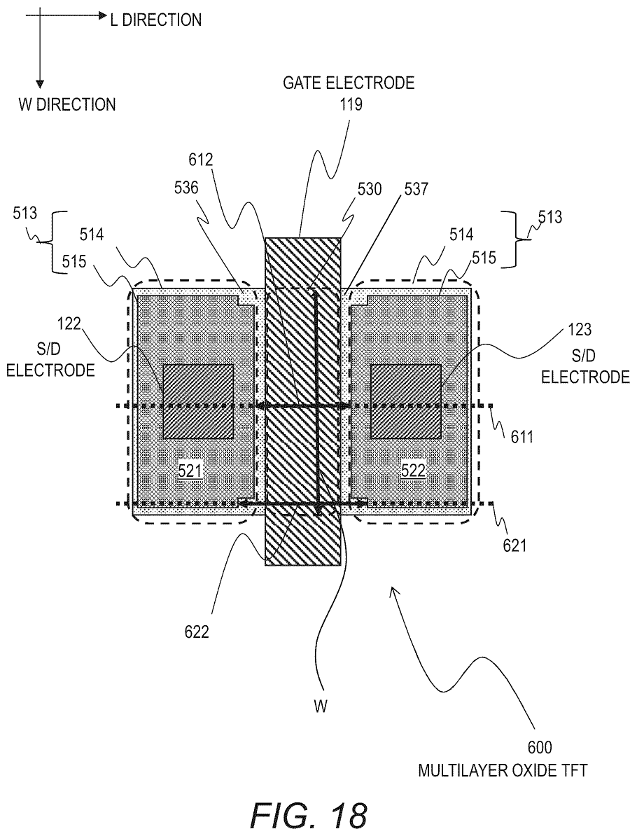

Still another configuration example of a multilayer oxide TFT is described. FIG. 18 is a schematic plan diagram of a structural example of the multilayer oxide TFT in FIG. 14. This multilayer oxide TFT includes offset regions that are more resistive than the source/drain regions between the channel region and each source/drain region. This configuration improves the drain breakdown voltage of the multilayer oxide TFT. In addition to this feature, the reliability of the TFT can be improved by varying the distance between the source region and the drain region depending on the location as described in the following.

L direction means the direction for defining the channel length of a TFT and W direction means the direction for defining the channel width of the TFT. The multilayer oxide TFT 600 includes a layered oxide region 513. The layered oxide region 513 consists of a lower oxide region 514 and an upper oxide region 515. There is an interface between the lower oxide region 514 and the upper oxide region 515. The lower oxide region 514 (an example of the first oxide layer) can be made of the same oxide as the lower oxide region 114 in FIG. 4. The upper oxide region 515 (an example of the second oxide layer) can be made of the same oxide as the upper oxide region 115 in FIG. 4.

The upper oxide region 515 is patterned on the lower oxide region 514; a region including the region overlapping the gate electrode 119 is removed. The upper oxide region 515 includes low-resistive regions 521 and 522. The region between the low-resistive regions 521 and 522 is removed so that a part of the top face of the lower oxide region 514 and the insulator layer 117 have an interface. In this example of FIG. 18, the distance between the low-resistive regions 521 and 522 differs depending on the position in the channel width W. The distance 622 between the low-resistive regions 521 and 522 at an end of the channel width W is longer than the distance 612 between the low-resistive regions 521 and 522 at a middle of the channel width W.

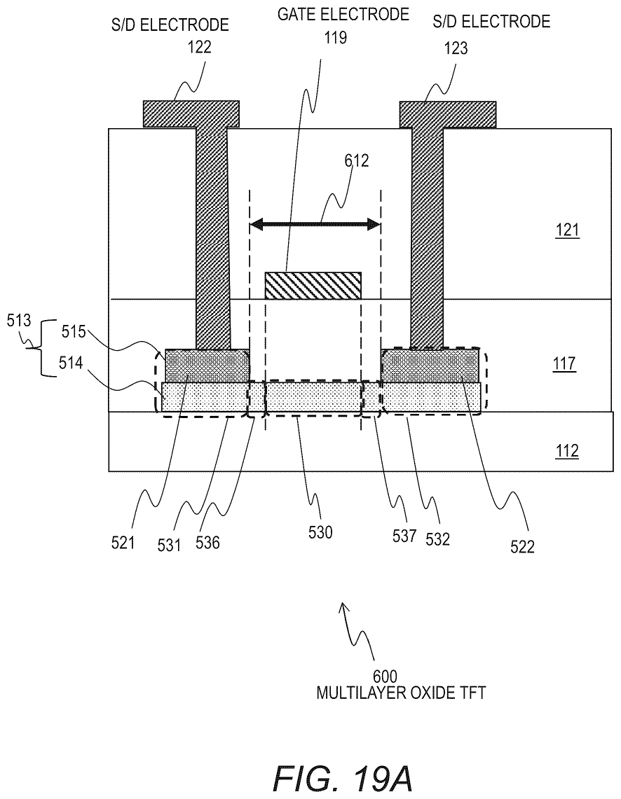

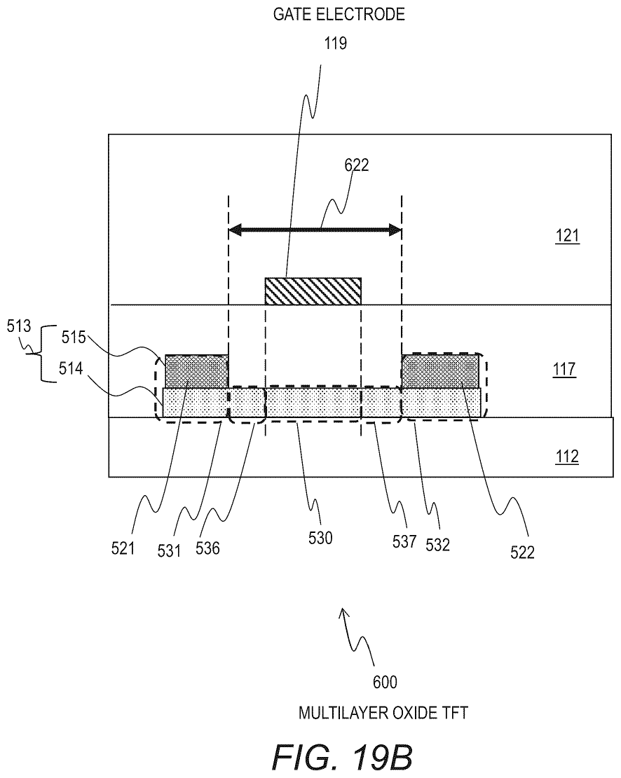

FIG. 19A illustrates the cross-section of the example of FIG. 18 along the center line 611 of the channel width W and FIG. 19B illustrates the cross-section of the example of FIG. 18 along the extension line 621 of an end of the channel width W. The distance 622 between the low-resistive regions 521 and 522 in FIG. 19B is longer than the distance 612 between the low-resistive regions 521 and 522 in FIG. 19A.

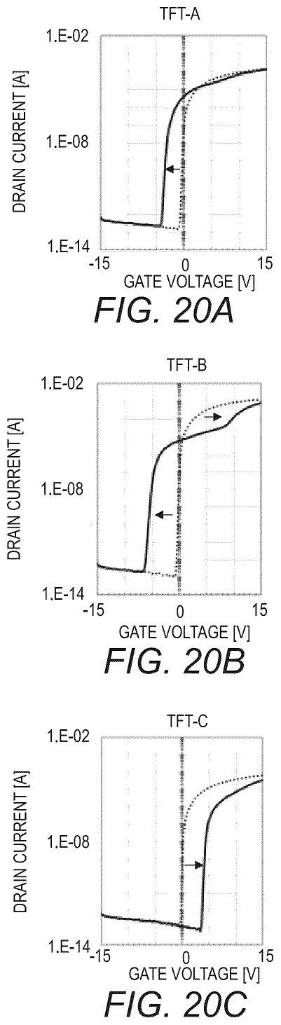

The structure illustrated in FIGS. 18, 19A, and 19B improves the reliability of the TFT. The reason is described with experimental results shown in FIGS. 20A, 20B, and 20C.

FIGS. 20A, 20B, and 20C provide results of evaluation on the reliability of three TFTs, TFT-A, TFT-B, and TFT-C. These TFTs are different in channel width W and/or the distance between low-resistive regions. The TFT-A has a 4-μm channel width and its low-resistive regions are 4 μm distant. The TFT-B has a 50-μm channel width and its low-resistive regions are 4 μm distant. The TFT-C has a 4-μm channel width and its low-resistive regions are 6 μm distant. Each graph shows the Id-Vg characteristic when the TFT is manufactured in a dotted line and the Id-Vg characteristic after the TFT is stressed in a solid line. The TFTs were stressed by applying 0 V to the source electrode and the drain electrode and +30 V to the gate electrode for one hour under the environment of 60° C.

The Id-Vg characteristic of the stressed TFT-A was shifted toward the negative direction as indicated in FIG. 20A. In this state, the drain current flows even if the gate voltage is 0 V; a critical problem is more likely to occur in the circuit operation.

As to the Id-Vg characteristic of the stressed TFT-B, the subthreshold region was shifted toward the negative direction but the region where the drain current is 1e-5 A or more was shifted toward the positive direction, exhibiting a hump characteristic as shown in FIG. 20B. It is known that the hump characteristic shows up when the channel region includes regions having different characteristics. The comparison with the result of the TFT-A indicates that the characteristic of the regions close to the ends of the channel width W was shifted toward the negative direction. FIG. 20B tells that the phenomenon that the Id-Vg characteristic is shifted toward the negative direction occurs in the regions close to the ends of the channel width W. The Id-Vg characteristic of the stressed TFT-C was shifted toward the positive direction overall as shown in FIG. 20C. This result indicates that the shift toward the negative direction is avoided by increasing the distance between low-resistive regions. Under the shift toward the positive direction, the drain current does not flow when the gate voltage is 0 V; a critical problem hardly occurs in the circuit operation. However, the TFT-C has a lower ON-current than the TFT-A because of the long distance between the low-resistive regions.

In view of these experimental results, a TFT can improve its reliability while preventing the ON-current from lowering by increasing the distance between low-resistive regions only in the regions close to the ends of the channel width W where the Id-Vg characteristic is shifted toward the negative direction because of gate voltage stress but keeping the distance between the low-resistive regions unchanged in the region in the middle of the channel width Was illustrated in FIGS. 18, 19A, and 19B.

The manufacturing method in this embodiment is almost the same as the manufacturing method in Embodiment 5, expect that the pattern shape of the upper oxide region 515 is different.

This embodiment has a configuration such that the lower oxide region 514 (an example of the first oxide layer) is made of the same oxide as the lower oxide region 114 in FIG. 4, the upper oxide region 515 (an example of the second oxide layer) is made of the same oxide as the upper oxide region 115 in FIG. 4, and the upper oxide region 515 is patterned on the lower oxide region 514; however, a configuration such that the lower oxide region 514 (an example of the second oxide layer) is made of the same oxide as the upper oxide region 115 described with reference to FIGS. 4 and 5, the upper oxide region 515 (an example of the first oxide layer) is made of the same oxide as the lower oxide region 114, and the lower oxide region 514 is patterned on the insulator layer 112 is also applicable, like the application of Embodiment 6 to Embodiment 5.

As set forth above, embodiments of this disclosure have been described; however, this disclosure is not limited to the foregoing embodiments. Those skilled in the art can easily modify, add, or convert each element in the foregoing embodiments within the scope of this disclosure. A part of the configuration of one embodiment can be replaced with a configuration of another embodiment or a configuration of an embodiment can be incorporated into a configuration of another embodiment.

What is claimed is:

1. A thin-film transistor substrate comprising:
a substrate;
a thin-film transistor on the substrate,
wherein the thin-film transistor includes:
a gate electrode;
a layered oxide region located between the substrate and the gate electrode; and
a gate insulating layer located between the layered oxide region and the gate electrode,
wherein the layered oxide region includes:
a channel region covered with the gate electrode;
source/drain regions located outer than the gate electrode;
a first oxide layer made of a first oxide; and
a second oxide layer made of a second oxide different from the first oxide,
wherein the first oxide layer and the second oxide layer have an interface therebetween,
wherein the channel region includes a first region of the first oxide layer,
wherein each of the source/drain regions includes a second region of the first oxide layer and a first region of the second oxide layer laid one above the other,
wherein the first region of the second oxide layer has a lower resistivity than the second region of the first oxide layer,
wherein an amount of first impurity atoms required for the second region of the first oxide layer to have a resistivity equal to a resistivity of the first region of the second oxide layer is larger than an amount of the first impurity atoms contained in the first region of the second oxide layer, and
wherein a distance between a peak position in a concentration profile of the first impurity atoms in a layering direction and a top face of the first region of the second oxide layer is shorter than a distance between the peak position and a top face of the second region of the first oxide layer.

2. The thin-film transistor substrate according to claim 1, wherein the channel region further includes a second region of the second oxide layer.

3. The thin-film transistor substrate according to claim 1,
wherein the first oxide and the second oxide are oxides containing indium, and
wherein an atomic percentage of indium in the first oxide is larger than an atomic percentage of indium in the second oxide.

4. The thin-film transistor substrate according to claim 3,
wherein an atomic percentage of indium in an elemental combination other than oxygen of the first oxide is not less than 50 atm %, and
wherein an atomic percentage of indium in an elemental combination other than oxygen of the second oxide is less than 50 atm %.

5. The thin-film transistor substrate according to claim 1, wherein the first oxide has a higher mobility than the second oxide.

6. The thin-film transistor substrate according to claim 1, wherein the peak position is located in a vicinity of the top face of the first region of the second oxide layer.

7. The thin-film transistor substrate according to claim 1, wherein the first oxide layer is a lower layer and the second oxide layer is an upper layer.

8. The thin-film transistor substrate according to claim 1, wherein the first oxide layer is an upper layer and the second oxide layer is a lower layer.

9. The thin-film transistor substrate according to claim 7,
wherein the layered oxide region further includes a third oxide layer above the second oxide layer,
wherein the third oxide layer and the second oxide layer have an interface therebetween,
wherein the first oxide has a higher mobility than the second oxide,
wherein an oxide of the third oxide layer has a higher mobility than the second oxide,
wherein the channel region further includes a second region of the second oxide layer and a first region of the third oxide layer, and
wherein each of the source/drain regions further includes a second region of the third oxide layer.

10. The thin-film transistor substrate according to claim 1,
wherein the layered oxide region includes offset regions each located between a source/drain region and the channel region and outer than the gate electrode and the offset regions are more resistive than the source/drain regions,
wherein the channel region is the first region of the first oxide layer, and
wherein each offset region is a third region of the first oxide layer.

11. The thin-film transistor substrate according to claim 10, wherein distance between one of the source/drain regions and the other source/drain region located opposite across the gate electrode differs depending on position in a channel width of the thin-film transistor.

12. The thin-film transistor substrate according to claim 11, wherein a distance between one of the source/drain regions and the other source/drain region located opposite across the gate electrode at an end of a channel width of the thin-film transistor is longer than a distance between the source/drain regions at a middle of the channel width.

13. A method of manufacturing a thin-film transistor, the method comprising:
producing a layered oxide region including a first oxide layer and a second oxide layer laid one above the other;
producing an insulating layer above the layered oxide region;
producing a gate electrode above the insulating layer; and
implanting impurity ions to the layered oxide region using the gate electrode as a mask to reduce resistivity of parts of the second oxide layer,
wherein an amount of impurity ions to be implanted for the first oxide layer to have a resistivity equal to a resistivity of the parts of the second oxide layer is larger than an amount of impurity ions implanted to the parts of the second oxide layer, and
wherein a distance between a peak position of a concentration profile of impurity ions in the implanting and a top face of the second oxide layer is shorter than a distance between the peak position and a top face of the first oxide layer.
